(19) United States
(12) Patent Application Publication
(10) Pub. No.: US 2008/0124891 A1
(43) Pub. Date: May 29, 2008

(54) Method for Preventing Wafer Edge Peeling in Metal Wiring Process

(75) Inventors: Kegang Zhang, Shanghai (CN); Hunglin Chen, Shanghai (CN); Yin Long, Shanghai (CN); Qiliang Ni, Shanghai (CN); Wenlei Chen, Shanghai (CN); Yanbo Shangguan, Shanghai (CN); Xiaorong Zhu, Shanghai (CN)

Correspondence Address: SQUIRE, SANDERS & DEMPSEY L.L.P., 1 MARITIME PLAZA, SUITE 300, SAN FRANCISCO, CA, 94111, US

(73) Assignee: Semiconductor Manufacturing International (Shanghai) Corporation, Shanghai (CN)

(21) Appl. No.: 11/865,700

(22) Filed: Oct. 1, 2007

(30) Foreign Application Priority Data
Nov. 28, 2006 (CN) 200610118842.2

(51) Int. Cl. H01L 21/76

(52) U.S. Cl. 438/425; 257/E21.54

(57) ABSTRACT

A method for preventing wafer edge peeling in a metal wiring process. A buffer layer is formed between a diffusion barrier layer of a metal wiring substructure and a semiconductor substrate. The buffer layer is an insulating dielectric layer, preferably a silicon oxide layer, or a polysilicon layer. The silicon oxide layer is formed in a process for forming a Shallow Trench Isolation (STI) structure. Using the above processes, the structure of direct contact between the diffusion barrier layer of the metal wiring structure and the semiconductor substrate can be avoided, and hence wafer edge peeling can be avoided without any modification to a conventional semiconductor fabrication procedure and with low cost and improved operability. This method is applicable to various semiconductor fabrication processes.

### FIELD OF THE INVENTION

The present invention relates to a method for preventing wafer edge peeling, and more particularly to a method for preventing wafer edge peeling during formation of a metal wiring structure.

### BACKGROUND OF THE INVENTION

In general, a semiconductor fabrication procedure involves formation of an Integrated Circuit (IC) device on a silicon wafer through a deposition process, a photolithography process, an etch process, etc. During the fabrication of the device, generally an approximately 3 mm-wide edge of a wafer is not used for the formation of the IC device. For a wafer as shown in FIG. 1, a wafer edge 1 is just a part of the wafer which is not used for the device fabrication.

However, several metal layers and dielectric layers need to be deposited during the fabrication of the semiconductor device, and normally may be deposited at the wafer edge 1 as well. In a subsequent process such as metal deposition, chemical-mechanical polishing or annealing, granules of the dielectric and metal layers deposited at the wafer edge 1 tend to be peeled off from the surface of the semiconductor wafer, and these peeled granules may contaminate the semiconductor wafer. Therefore, the metal and dielectric layers disposed at the wafer edge 1 shall be removed in time. As disclosed in Chinese Patent Application No. 01139857, for example, a method for removing a dielectric layer at a circumferential edge of a wafer through a cutter can prevent the dielectric layer from contaminating the semiconductor wafer.

In the semiconductor fabrication, a metal material with a relatively high conductivity is typically used for wiring so as to interconnect individual devices to form an IC. A metal Copper is of low resistance, high electromigration performance, etc., and is well capable of releasing stress, and therefore has become a commonly used wiring material. However, the Copper is liable to diffuse into a general insulating material, and thus may be eroded, resulting in defects such as lowered adherence, occurrence of delamination, formation of voids, electrical abnormality of the circuit, etc. For this reason, during formation of a copper wiring structure, such as a damascene or dual-damascene structure, a diffusion barrier layer is typically formed between the copper and the insulating layer so as to reduce the occurrence of the above defects. At present, the diffusion barrier layer is mostly of a compound composed of a diffusion barrier material selected from Titanium (Ti), Tantalum (Ta), Tungsten (W), Ruthenium (Ru), Zirconium (Zr), Hafnium (Hf), Vanadium (V), Niobium (Nb), Chromium (Cr), Molybdenum (Mo), etc., and at least one reactive gas including Oxygen, Nitrogen and/or Carbon.

In fabrication of the metal wiring, because the metal material forming the diffusion barrier layer at the wafer edge comes into a direct contact with the silicon of the wafer substrate after the formation of the diffusion barrier layer, and there may be large stress between the metal material forming the diffusion layer and the silicon of the wafer substrate, the wafer edge can be peeled off considerably, as shown in FIG. 2A through FIG. 2D.

### SUMMARY OF THE INVENTION

In view of the above, an object of the present invention is to prevent a wafer edge from being peeled off during formation of a metal wiring structure, particularly a diffusion barrier layer of the metal wiring structure.

To this end, an embodiment of the present invention provides a method for preventing wafer edge peeling in a metal wiring process, including forming a buffer layer between a diffusion barrier layer of a metal wiring substructure and a semiconductor substrate at a wafer edge. Preferably, the buffer layer may be an insulating dielectric layer or a polysilicon layer.

Preferably, the insulating dielectric layer may be a silicon oxide layer.

Preferably, the silicon oxide layer may be formed in a process for forming a Shallow Trench Isolation (STI) structure.

Preferably, the process for forming the buffer layer may include the following steps of:

forming a liner oxide layer and an erosion barrier layer sequentially over the semiconductor substrate with a zero mark, the semiconductor substrate including an edge part and a body part;

etching the erosion barrier layer, the liner oxide layer and the semiconductor substrate sequentially to form an opening area at the edge part and an isolation trench at the body part of the semiconductor substrate;

depositing an isolation oxide layer to fill the opening formed at the edge part of the semiconductor substrate, the isolation trench and the zero mark;

planarizing the isolation oxide layer until the erosion barrier layer is exposed; and

removing the isolation oxide layer in the zero mark.

Preferably, the opening formed at the edge part may be 1˜1.5 mm in width.

The embodiment of the present invention can be advantageous over the prior art at least in the following aspects.

1. Through forming the insulating dielectric layer, the polysilicon layer, etc. as the buffer layer between the diffusion barrier layer of the metal wiring structure and the semiconductor substrate, to avoid direct contact of the diffusion barrier layer of the metal wiring structure with the semiconductor substrate, and hence wafer edge peeling can be prevented.

2. For simplicity of the semiconductor process for introducing the buffer layer, the silicon oxide layer can be used as the buffer layer, and also can be introduced at the wafer edge during the formation of the STI structure without any modification to a conventional semiconductor fabrication procedure and with low cost and improved operability. This method is applicable to various semiconductor fabrication processes.

### BRIEF DESCRIPTIONS OF THE DRAWINGS

FIG. 1 is a structural diagram of a wafer and an edge thereof;

FIG. 2A through FIG. 2D are enlarged views showing much contaminant peeled off from an edge of a wafer is dispersed over the wafer;

FIG. 3 is a structural diagram of a buffer layer being introduced between a semiconductor substrate and a diffusion barrier layer at a wafer edge according to an embodiment of the present invention;

FIG. 4A is a structural plan view of a wafer with a zero mark;

FIG. 4B is a structural sectional view of a wafer with a zero mark;

FIG. 5A through FIG. 5H are structural sectional views illustrating a process flow for forming an isolation trench and exposing a zero mark in the prior art;

FIG. 6A through FIG. 6H are structural sectional views illustrating a process flow for forming an isolation trench and exposing a zero mark according to an embodiment of the present invention;

FIG. 7 is a comparative diagram of both a failure rate and the number of defects for a device fabricated according to an embodiment of the present invention and those in the prior art; and

FIG. 8 is a comparative diagram of a yield rate of devices fabricated according to an embodiment of the present invention and that in the prior art.

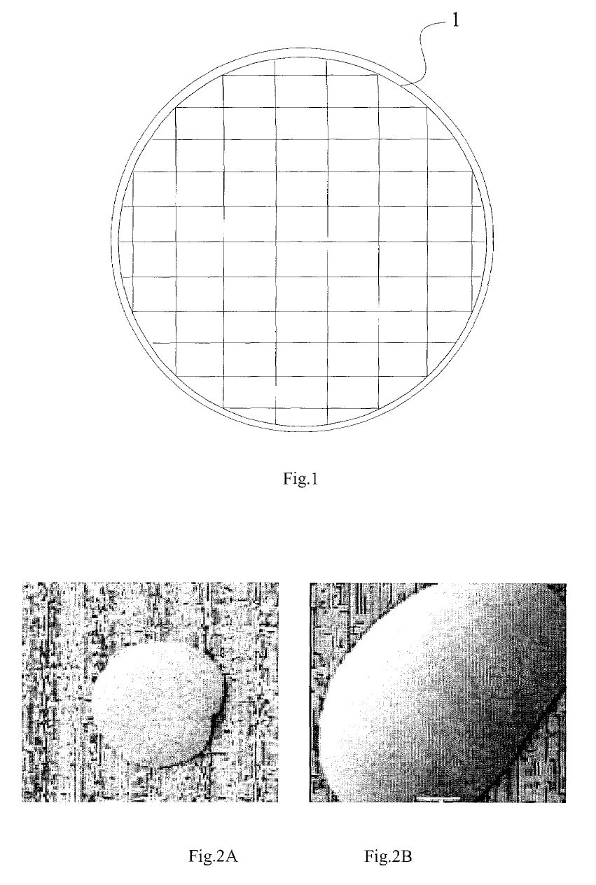

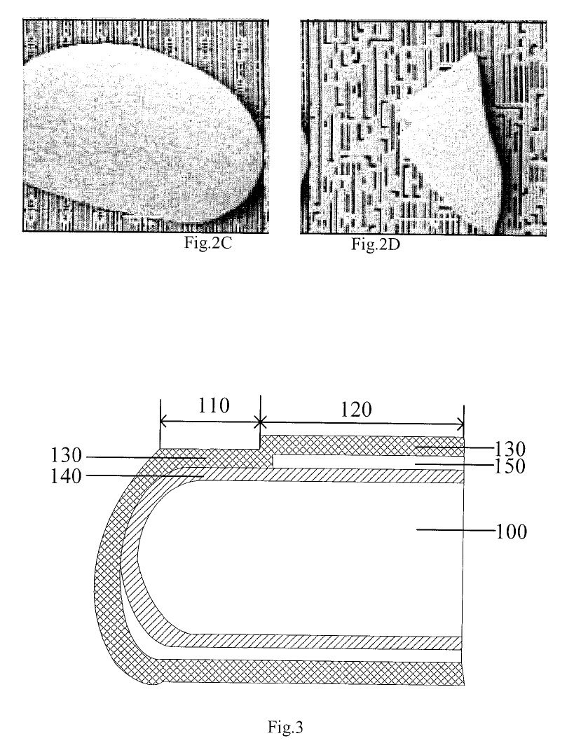

### DETAILED DESCRIPTIONS OF THE EMBODIMENTS

The present invention will be described in detail with reference to the drawings and the embodiments thereof.

Investigations according to the present invention show that a main reason for peeling of a wafer edge during formation of a metal wiring structure lies in large contact stress due to the fact that a metal material forming a diffusion barrier layer directly contacts with a semiconductor substrate at the wafer edge. In order to obviate the occurrence of the peeling of the wafer edge, a buffer layer can be formed between the diffusion barrier layer and the semiconductor substrate at the wafer edge and bevel, and thus the large contact stress between the metal material of the diffusion barrier layer and the semiconductor substrate can be avoided.

In view of the above, an embodiment of the present invention presents a method for preventing a wafer edge, which is a bare portion of a semiconductor substrate, from being peeled off, wherein a dielectric layer that would otherwise be peeled off is a diffusion barrier layer deposited during formation of metal wiring. In this case, a buffer layer, e.g. an insulating dielectric layer, a polysilicon layer, etc., can be formed between the semiconductor substrate and the diffusion barrier layer.

Referring to FIG. 3 illustrating a structural diagram of a buffer layer being introduced between a semiconductor substrate and a diffusion barrier layer at a wafer edge, numeral 110 indicates a wafer edge, and numeral 120 indicates a wafer body for formation of a semiconductor device. For a clear structural view of the wafer edge 110, the area of the wafer edge 110 is enlarged in FIG. 3, and only the area of the wafer body 120 adjacent to the wafer edge 110 is shown. Numeral 100 indicates a semiconductor substrate, and as shown in FIG. 3, at the wafer edge 110, a buffer layer 140, e.g. an insulating dielectric layer, a polysilicon layer, etc., preferably of silicon oxide, is formed between the semiconductor substrate 100 and the diffusion barrier layer 130. Additionally at the wafer body 120, a dielectric layer 150 is formed between the buffer layer 140 and the diffusion barrier layer 130. In this regard, the dielectric layer 150 is merely an illustrative representation for showing that at the wafer body 120, one or more structures may be formed between the semiconductor substrate 100 and the diffusion barrier 130, and hence has no influence on the scope of the present invention.

In a conventional semiconductor fabrication procedure, introducing the buffer layer in any process for the procedure may influence both that procedure and film stress of the wafer body 120 for formation of a semiconductor device, and hence may become a new source of defects. In this case, another critical factor for the embodiment of the present invention is the selection of a semiconductor fabrication process for introducing the buffer layer without influence or great influence on the semiconductor fabrication procedure.

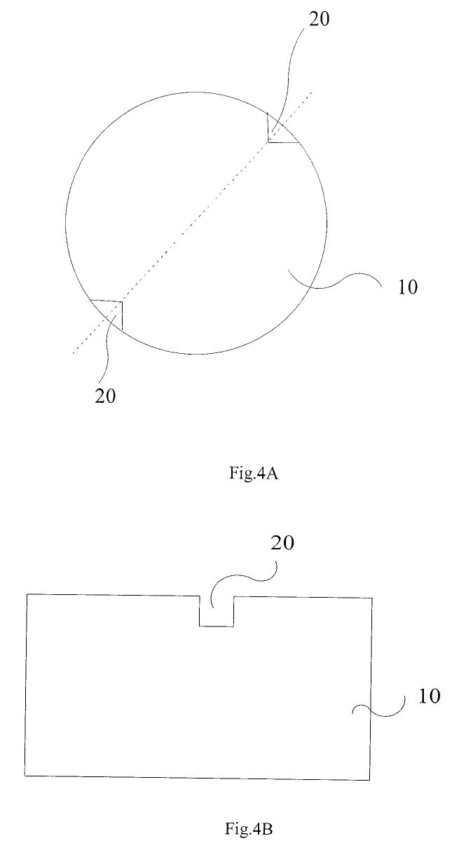

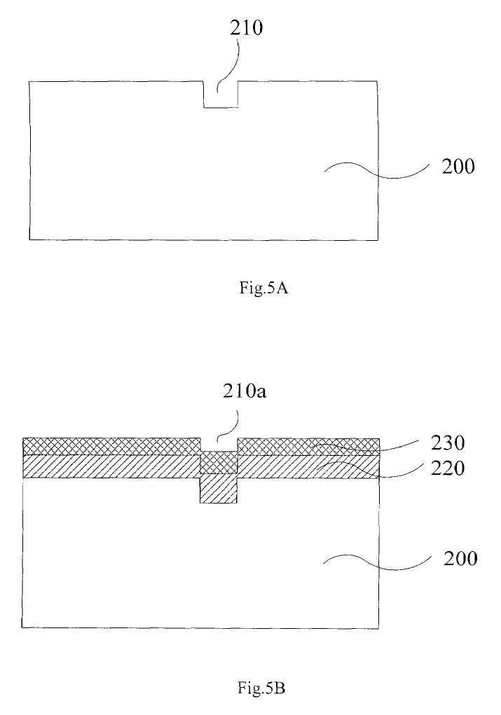

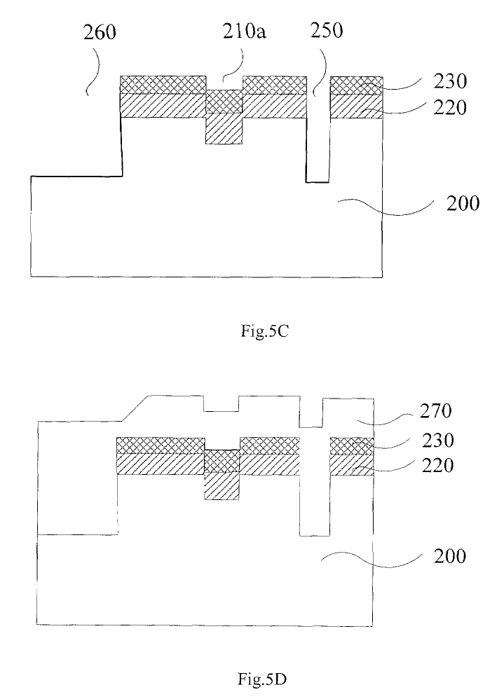

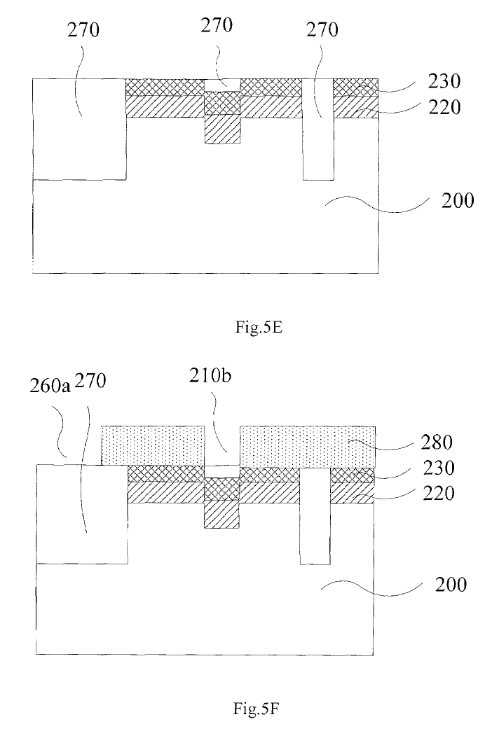

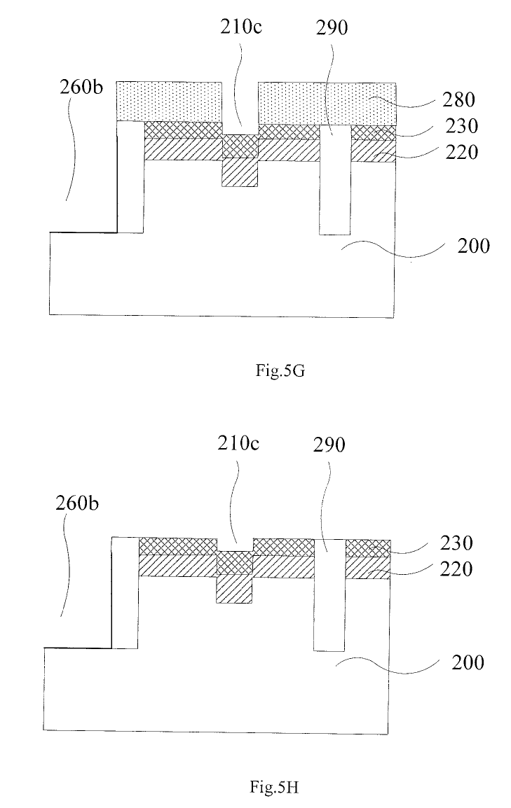

There is a zero mark on the wafer for self-alignment in the photolithography process, as shown in FIG. 4A, where numeral 10 indicates a wafer, and numerals 20 indicate two zero marks on the wafer 10, and as shown in FIG. 4B illustrating a structural sectional view of the wafer viewed perpendicularly to a line along which the two zero marks are arranged. In a process for forming one or more film layers of a semiconductor device, e.g. forming an isolation structure, an insulating material may be deposited at the location of the zero marks. In order to make the zero marks still available, the insulating material in the zero mark shall be removed. In the prior art, the insulating material deposited at the wafer edge is typically removed directly in the process for forming the isolation structure and removing the insulating material filled at the location of the zero marks, particularly as shown in FIG. 5A through FIG. 5H.

Referring to FIG. 5A, a semiconductor substrate 200 is provided with a zero mark 210 thereon. Then referring to FIG. 5B, a liner oxide layer 220 of silicon oxide and an erosion barrier layer 230 of silicon nitride are deposited sequentially over the semiconductor substrate 200 through a Chemical Vapor Deposition (CVD) method, and as shown, there is still a zero mark 210a on the erosion barrier layer 230.

Referring to FIG. 5C, a photoresist layer (not shown) is formed on the erosion barrier layer 230, and is further exposed and developed, and thus a photoresist opening is formed at a wafer edge and a location where an isolation structure is designed to be formed. Thereafter, the erosion barrier layer 230, the liner oxide layer 220 and the semiconductor substrate 200 are etched via the photoresist opening. Thus, an opening 260 with a width of 1˜1.5 mm is formed at an edge of the semiconductor substrate 200, and an isolation trench 250 is formed at a body part of the semiconductor substrate 200 for formation of a semiconductor device.

Referring to FIG. 5D, an insulating material is deposited on the erosion barrier layer 230, in the opening 260 formed at the edge of the semiconductor substrate 200, and in the isolation trench 250, thus forming an isolation insulating layer 270 preferably of silicon oxide preferably through a CVD method, which fills up the opening 260 formed at the edge of the semiconductor substrate 200 and the isolation trench 250 as well as the zero mark 210 on the erosion barrier layer 230. Further referring to FIG. 5E, the isolation insulating layer 270 is planarized through a Chemical Mechanical Polishing (CMP) process, so that the isolation insulating layer 270 is provided with a planarized surface, and the erosion barrier layer 230 is exposed completely.

Referring to FIG. 5F, a photoresist layer 280 is formed on the isolation insulating layer 270 and the erosion barrier layer 230, and is further exposed and developed to form at the edge of the semiconductor substrate, a photoresist opening 260a which in a practical process, has a width equal to or slightly less than that of the opening 260 formed at the edge of the semiconductor substrate 200, and to form a photoresist opening 210b above the zero mark 210. Referring to FIG. 5G, the isolation insulating layer 270 is etched using the photoresist as a mask, thus forming an opening 260b at the edge 260a of the semiconductor substrate and an opening 210c at a location corresponding to the zero mark 210b. Further referring to FIG. 5H, the photoresist layer 280 is removed. In this way, no film layer can remain at the wafer edge 260b, and the zero mark 210c can be exposed.

In connection with the processes described with reference to FIG. 5A through FIG. 5H, the insulating material filled at the edge of the semiconductor substrate can be removed simultaneously with the removing of that filled at the zero mark. In order to prevent peeling defect at the edge of the semiconductor substrate due to large stress arising from the direct contact between the diffusion barrier layer and the semiconductor substrate in fabrication of the metal wiring structure in the present invention, it is found after numerous experiments that an isolation insulating layer filling an isolation trench can be introduced at the edge of the semiconductor substrate in the fabrication of an isolation structure, thus preventing the diffusion barrier layer at the edge of the semiconductor substrate from being peeled off from the semiconductor substrate through a simple process without influence on a subsequent process for the semiconductor fabrication procedure.

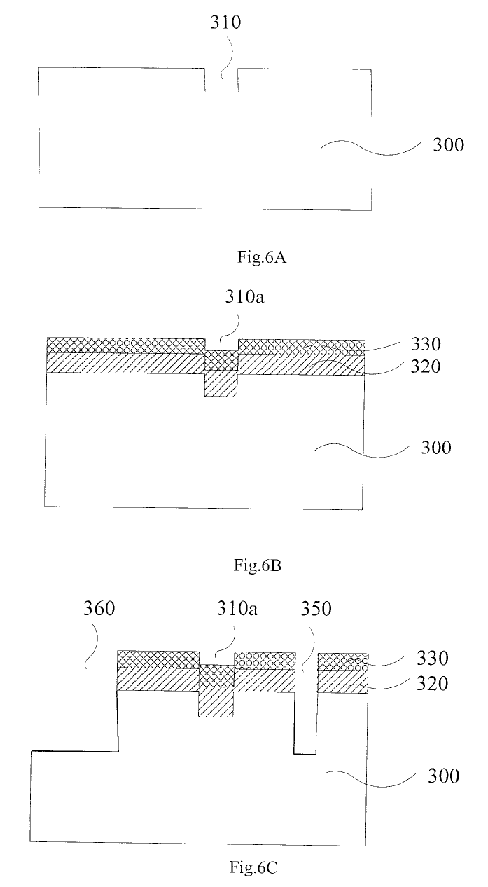

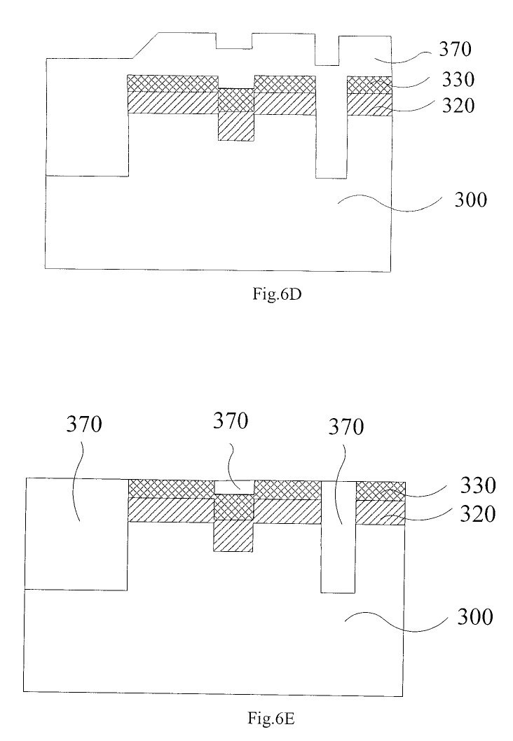

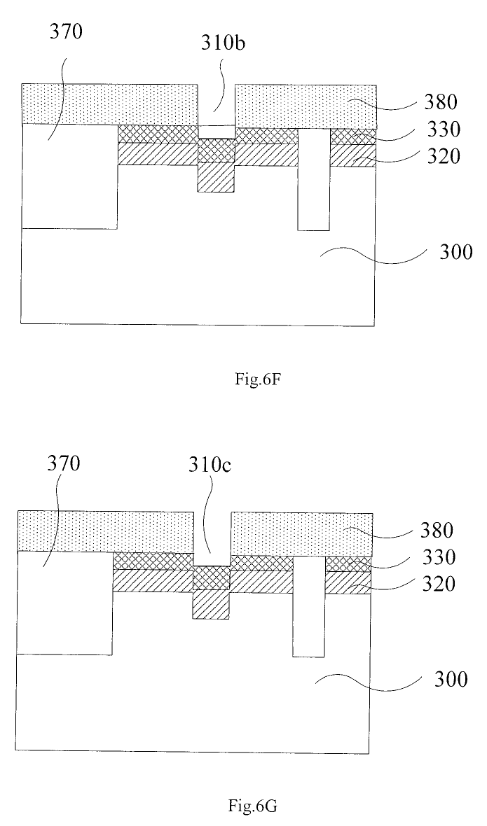

With reference to FIG. 6A through FIG. 6Q specific processes for introducing, at an edge of a semiconductor substrate, an isolation insulating layer filling an isolation trench in a procedure for forming an isolation structure according to an embodiment of the present invention. Firstly referring to FIG. 6A, a semiconductor substrate 300 is provided with a zero mark 310 thereon. Then referring to FIG. 6B, a liner oxide layer 320 of silicon oxide and an erosion barrier layer 330 of silicon nitride are deposited sequentially over the semiconductor substrate 300 through a CVD method, and as shown, there is still a zero mark 310a on the erosion barrier layer 330.

Referring to FIG. 6C, a photoresist layer (not shown) is formed on the erosion barrier layer 330, and is further exposed and developed, and thus a photoresist opening is formed at a wafer edge and a location where an isolation structure is designed to be formed. Thereafter, the erosion barrier layer 330, the liner oxide layer 320 and the semiconductor substrate 300 are etched via the photoresist opening. Thus, an opening 360 with a width of 1˜1.5 mm is formed at an edge of the semiconductor substrate 300, and an isolation trench 350 is formed at a body part of the semiconductor substrate 300 for formation of a semiconductor device.

Referring to FIG. 6D, an insulating material is filled on the erosion barrier layer 330, in the opening 360 formed at the edge of the semiconductor substrate 300, and in the isolation trench 350, thus forming an isolation insulating layer preferably of silicon oxide 370 preferably through a CVD method, which fills up the opening 360 formed at the edge of the semiconductor substrate 300 and the isolation trench 350 as well as the zero mark 310a on the erosion barrier layer 330. Further referring to FIG. 6E, the isolation insulating layer 370 is planarized through a CMP process, so that the isolation insulating layer 370 is provided with a planarized surface, and the erosion barrier layer 330 is exposed completely.

Referring to FIG. 6F, a photoresist layer 380 is formed on the isolation insulating layer 370 and the erosion barrier layer 330, and is further exposed and developed to form a photoresist opening 310b above the zero mark 310. Referring to FIG. 6Q the isolation insulating layer 370 is etched using the photoresist as a mask, thus forming a zero mark 310c at a location corresponding to the zero mark 310b. Further referring to FIG. 6H, the photoresist layer 380 is removed.

Using the above processes, without any modification to the semiconductor fabrication procedure or introduction of any additional process, it only need to adapt a photoresist mask pattern exposing a zero mark after formation of an isolation trench, so as to introduce an isolation insulating layer acting as a buffer layer at an edge of a semiconductor substrate, thus obviating peeling defects due to direct contact between a diffusion barrier layer and the semiconductor substrate in a subsequent process for a metal wiring structure.

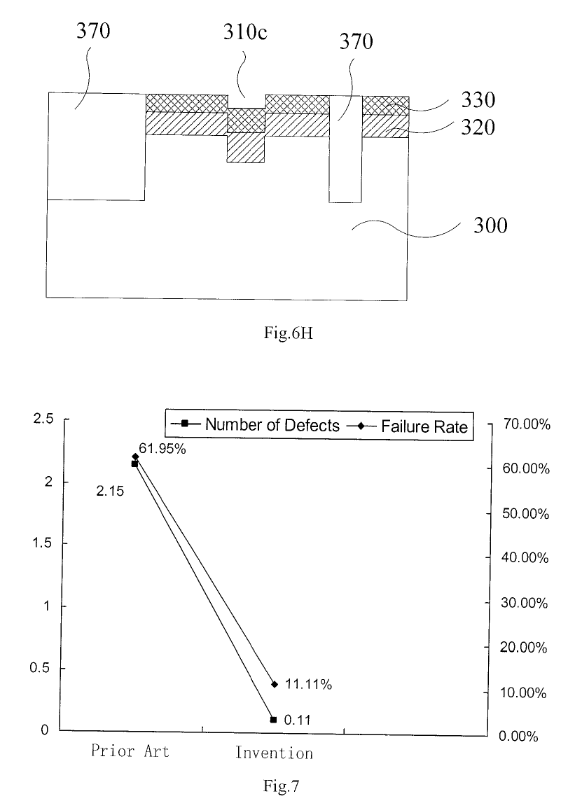

As shown in FIG. 7 illustrating a comparative diagram of both a failure rate and the number of defects for a device fabricated according to an embodiment of the present invention and those in the prior art, the failure rate and the number of defects arising from the wafer edge peeling in the prior art are 61.95% and 2.15 respectively, while the failure rate and the number of defects arising from the wafer edge peeling according to the embodiment of the present invention are 11.11% and 0.11 respectively.

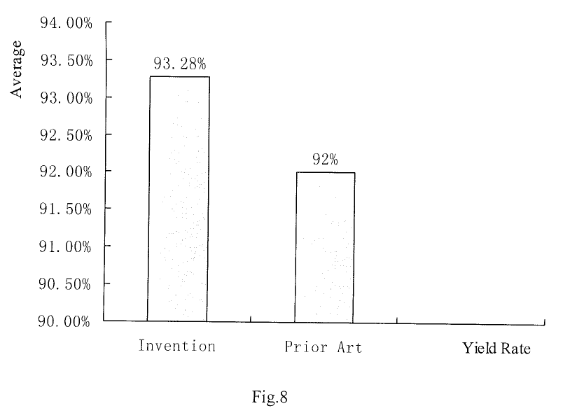

As shown in FIG. 8 illustrating a comparative diagram of a yield rate of devices fabricated according to an embodiment of the present invention and that in the prior art, the yield rate of devices has been increased from 92% in the prior art to 93.28% in the embodiment of the present invention, thus saving the production cost for a manufacturer.

While the preferred embodiments of the present invention have been described as above, it shall be appreciated that the scope of the present invention shall not be limited thereto, and those skilled in the art can make various variations and modifications to the embodiments without departing from the scope of the present invention. Thus, it is intended that all such variations and modifications shall fall within the scope of the present invention as solely defined in the claims thereof.

What is claimed is:

1. A method for preventing wafer edge peeling in a metal wiring process, comprising forming a buffer layer between a diffusion barrier layer of a metal wiring substructure and a semiconductor substrate at a wafer edge.

2. The method according to claim 1, wherein the buffer layer is an insulating dielectric layer or a polysilicon layer.

3. The method according to claim 2, wherein the insulating dielectric layer is of silicon oxide.

4. The method according to claim 1, wherein the buffer layer is formed in a process for forming a Shallow Trench Isolation (STI) structure.

5. The method according to claim 2, wherein the buffer layer is formed in a process for forming a Shallow Trench Isolation (STI) structure.

6. The method according to claim 3, wherein the buffer layer is formed in a process for forming a Shallow Trench Isolation (STI) structure.

7. The method according to claim 4, wherein the process of forming the buffer layer comprises:
forming a liner oxide layer and an erosion barrier layer sequentially over the semiconductor substrate with a zero mark, the semiconductor substrate comprising an edge part and a body part;
etching the erosion barrier layer, the liner oxide layer and the semiconductor substrate sequentially to form an opening area at the edge part and an isolation trench at the body part of the semiconductor substrate;
depositing an isolation oxide layer to fill the opening formed at the edge part of the semiconductor substrate, the isolation trench and the zero mark;
planarizing the isolation oxide layer until the erosion barrier layer is exposed; and
removing the isolation oxide layer in the zero mark.

8. The method according to claim 5, wherein the process of forming the buffer layer comprises:
forming a liner oxide layer and an erosion barrier layer sequentially over the semiconductor substrate with a zero mark, the semiconductor substrate comprising an edge part and a body part;
etching the erosion barrier layer, the liner oxide layer and the semiconductor substrate sequentially to form an opening area at the edge part and an isolation trench at the body part of the semiconductor substrate;
depositing an isolation oxide layer to fill the opening formed at the edge part of the semiconductor substrate, the isolation trench and the zero mark;
planarizing the isolation oxide layer until the erosion barrier layer is exposed; and
removing the isolation oxide layer in the zero mark.

9. The method according to claim 6, wherein the process of forming the buffer layer comprises:
forming a liner oxide layer and an erosion barrier layer sequentially over the semiconductor substrate with a zero mark, the semiconductor substrate comprising an edge part and a body part;
etching the erosion barrier layer, the liner oxide layer and the semiconductor substrate sequentially to form an opening area at the edge part and an isolation trench at the body part of the semiconductor substrate;
depositing an isolation oxide layer to fill the opening formed at the edge part of the semiconductor substrate, the isolation trench and the zero mark;
planarizing the isolation oxide layer until the erosion barrier layer is exposed; and
removing the isolation oxide layer in the zero mark.

10. The method according to claim 7, wherein the opening formed at the edge part is 1˜1.5 mm in width.

11. The method according to claim 8, wherein the opening formed at the edge part is 1˜1.5 mm in width.

12. The method according to claim 9, wherein the opening formed at the edge part is 1˜1.5 mm in width.

13. The method according to claim 7, wherein the liner oxide layer is of silicon oxide, and the erosion barrier layer is of silicon nitride.

14. The method according to claim 8, wherein the liner oxide layer is of silicon oxide, and the erosion barrier layer is of silicon nitride.

15. The method according to claim 9, wherein the liner oxide layer is of silicon oxide, and the erosion barrier layer is of silicon nitride.

16. The method according to claim 7, wherein the isolation oxide layer is of silicon oxide.

17. The method according to claim 8, wherein the isolation oxide layer is of silicon oxide.

18. The method according to claim 9, wherein the isolation oxide layer is of silicon oxide.

19. The method according to claim 7, wherein the process for planarizing the isolation oxide layer uses a chemical-mechanical-polishing method.

20. The method according to claim 8, wherein the process for planarizing the isolation oxide layer uses a chemical-mechanical-polishing method.

21. The method according to claim 9, wherein the process for planarizing the isolation oxide layer uses a chemical-mechanical-polishing method.
